(19) United States
(12) Patent Application Publication
(10) Pub. No.: US 2013/0170823 A1
(43) Pub. Date: Jul. 4, 2013

(54) Mounting System for Electronics Device

(71) Applicants: David Arien McDonald, Merrimack, NH (US); Jonathan Alan Marks, Somerville, MA (US)

(72) Inventors: David Arien McDonald, Merrimack, NH (US); Jonathan Alan Marks, Somerville, MA (US)

(21) Appl. No.: 13/341,554

(22) Filed: Dec. 30, 2011

(51) Int. Cl. G03B 17/00; B23P 11/00; H05K 7/00

(52) U.S. Cl. 396/428; 248/316.1; 248/222.14; 29/525.03

(57) ABSTRACT

The present invention relates to electronic devices of a particular structure, and to a method and apparatus for engaging and holding such devices with the user's person, clothing, equipment or vehicle. The apparatus includes a bracket that engages with the electronic device and a cover that provides protection to the electronic device and a camera lens augmentation element. Additional elements provide engagement between flat or cylindrical surfaces. The apparatus facilitates convenient carry, access and secure attachment of an electronic device during participation in a physical activity.

### BACKGROUND

1. Field of the Invention

The present invention relates generally to the field of mounting electronic devices and more particularly to system that promotes carrying, accessing, using and stowing an electronic device while participating in physical activities such as surfing, cycling, skiing, kayaking and the like.

2. Description of the Problem

The need arises to secure specific electronic devices to one's person or to a helmet or other piece of clothing or equipment to facilitate carrying, accessing, using and stowing of such an electronic device that records images, video and sound.

The present disclosure relates to electronic devices of a particular structure, and to a method and apparatus for engaging such devices with the user's person, clothing, equipment or vehicle. The apparatus comprises a bracket that engages with the electronic device and a cover that provides protection to the electronic device and a camera lens augmentation element. Additional elements provide engagement between flat or cylindrical surfaces. The apparatus facilitates convenient carry, access and secure attachment of an electronic device during participation in a physical activity.

The present embodiment promotes carrying, accessing, using and stowing an electronic device while participating in physical activities such as surfing, cycling, skiing, kayaking and so forth. Various straps and elastic materials have been employed in attempts to secure cameras, video and/or sound recording equipment during use. Digital electronic devices provide increasing quality photographs and video with increasingly smaller envelopes.

It is an object of the present invention to provide an improved method of securing an electronics device to one's person, or equipment such as helmet, ski poles, handle bars or the like, allowing the user to employ the electronic device while leaving hands free, when taking part in activities.

It is another primary object to provide an apparatus that engages securely with the electronics device and further engages with the body and with equipment.

### SUMMARY OF THE INVENTION

The present invention relates to electronic devices of a particular structure, and to a method and apparatus for engaging such devices with the user's person, clothing, equipment or vehicle. The electronics device illustrated can be a hand-held phone, camera, video camera, recorder, player, memory storage device with internet/cell-phone connectivity. Although many styles and shapes are available for such devices, the method used to engage with such a device and the apparatus employed to further engage with a user's body or equipment is disclosed. A bracket made of a durable semi-rigid material such as polymers, composites or metal, provides flexible tabs that partially surround the electronics device and has features that engage with straps, screws, plastic tie straps, magnets or other fastening hardware. A cover comprising a protective shell that mates with both the electronics device and the bracket includes an additional lens that mates with the camera lens included in the electronics device. The additional lens may include optical augmentation features such as a wide angle view, telephoto, telescopic or other features associated with camera lenses.

As understood by one skilled in the art, the formal principles the present disclosure are not restricted to a specific electronics device, and may apply to any electronics device of similar structure. For the purpose of clarity a given example compact electronics device is shown and described.

These and other non-limiting features or characteristics of the present disclosure will be further described below.

### BRIEF DESCRIPTION OF THE DRAWINGS

The following is a brief description of the drawings, which are presented for the purposes of illustrating the disclosure set forth herein and not for the purposes of limiting the same.

FIG. 1 is a front right perspective, exploded view of the present disclosure.

FIG. 2 is a front, right, perspective view the mounting bracket.

FIG. 3 is a side, orthographic, section view of the bracket of FIG. 2.

FIG. 4 is a front perspective view of the bracket of FIG. 2 engaged with a strap.

FIG. 5 is a front perspective view of the bracket of FIG. 2 engaged with a screw and mounting hardware that engages with cylindrical objects.

FIG. 6 is a rear perspective view of the bracket of FIG. 2 engaged with a screw and mounting hardware that engages with cylindrical objects.

FIG. 7 is a side perspective view of the bracket of FIG. 2 engaged with the electronics device and with the cover of FIG. 1.

FIG. 8 is a side, exploded perspective view of the bracket, electronics device and cover of the configuration of FIG. 7.

FIG. 9 is a detail, side, exploded perspective view of the bracket, electronics device and cover of the configuration of FIG. 7.

FIG. 10 is a front, right, perspective view of an iteration of the mounting bracket of the embodiment.

FIG. 11 is a rear, right, perspective view of an iteration of the mounting bracket of the embodiment.

Several drawings and illustrations have been presented to aid in understanding the present invention. The scope of the present invention is not limited to what is shown in the figures.

### DETAILED DESCRIPTION

A more complete understanding of the components, processes, and apparatuses disclosed herein can be obtained by reference to the accompanying figures. These figures are intended to demonstrate the present disclosure and are not intended to show relative sizes and dimensions or to limit the scope of the disclosed embodiment(s).

Although specific terms are used in the following description, these terms are intended to refer only to particular structures in the drawings and are not intended to limit the scope of the present disclosure. It is to be understood that like numeric designations refer to components of like function.

The term “about” when used with a quantity includes the stated value and also has the meaning dictated by the context. For example, it includes at least the degree of error associated with the measurement of the particular quantity. When used in the context of a range, the term “about” should also be considered as disclosing the range defined by the absolute values of the two endpoints. For example, the range “from about 2 to about 4” also discloses the range “from 2 to 4.”

A clamping means of the present embodiment employs mechanical interference to securely engage an electronic device of a particular shape. The same mechanical interference may be employed to engage electronic devices of varying shapes. One example is illustrated, the principle may be employed with similar electronic devices as one skilled in the art will understand.

In one configuration of the embodiment, a clamping means is engaged with the back and a portion of the sides of an electronic device, a cover is engaged with the front and remaining portion of the sides of said electronic device. Once the electronic device is engaged with the clamping means, the clamping means may be further engaged with such hardware as is common to engage with equipment or a vehicle such as a bicycle or motorcycle. In another configuration of the embodiment, a clamping means is engaged with an electronic device and further engaged with a strap or belt to fasten the electronic device to the user's body, clothing or gear such as a helmet.

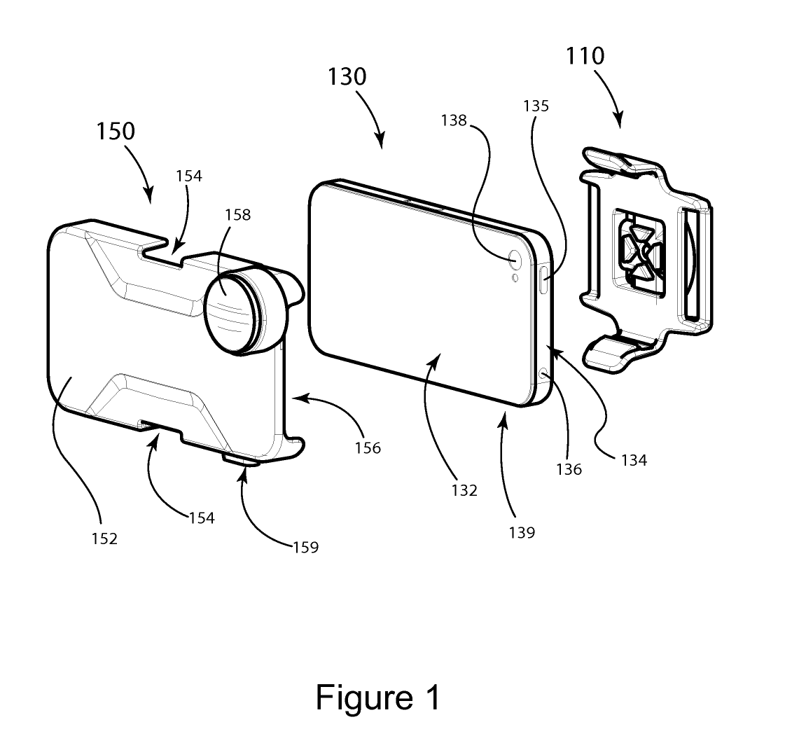

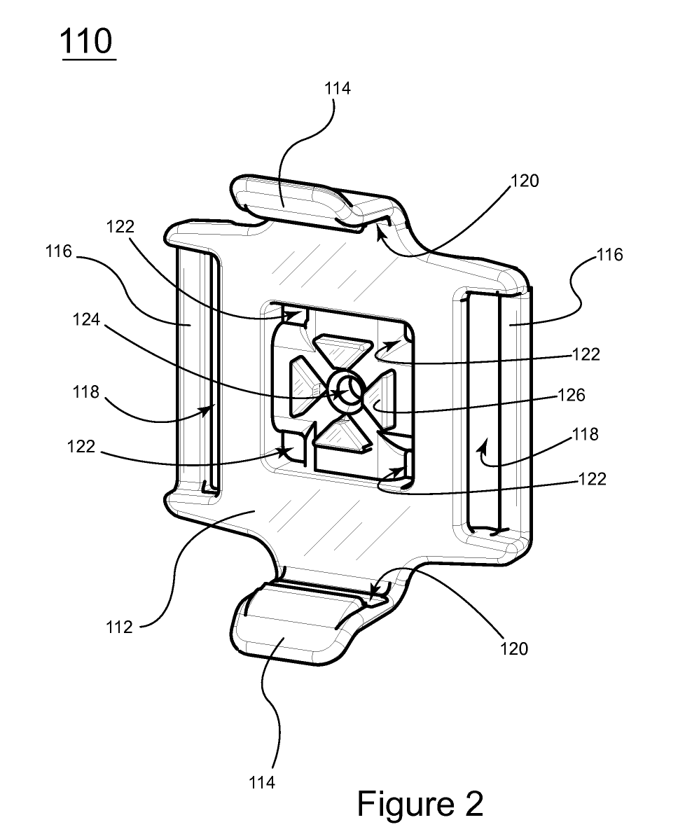

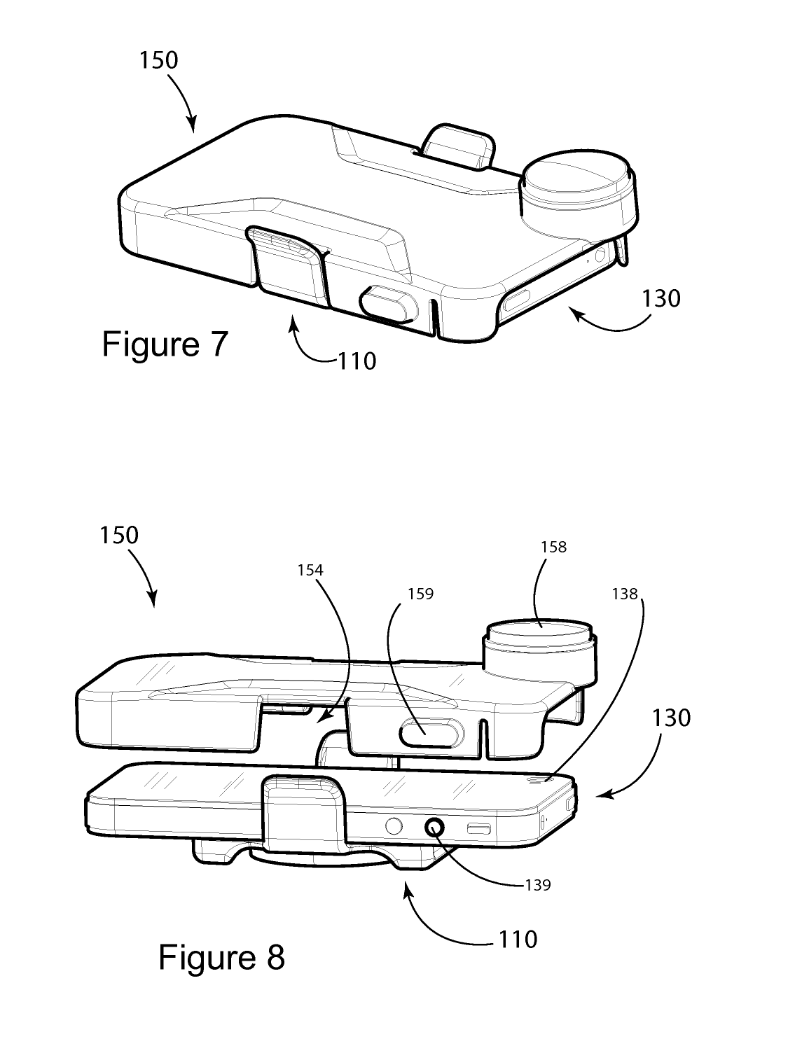

FIG. 1 is a perspective, exploded view of an embodiment of the present disclosure. FIG. 2 is a front, perspective view of a clamping device of the present disclosure. Referring to FIG. 1 and FIG. 2, an electronics device 130 has a body 132 with a camera lens 138, and a raised edge 134. The raised edge 134 has control buttons or plug ports, located about the perimeter of the device at locations such as those indicated by 135, 136, 139. A cover 150 engages with the electronic device 130. A primary surface 152 provides protection to the electronics device 130. A recess 154 aligns with portions of the clamping device 110. A lens 158 aligns with the camera lens 138 of the electronic device 130. The cover provides access to plug ports or buttons by a recess 156 or integrated cover 159. The integrated cover is explained in detail in FIG. 7 through FIG. 9.

The electronics device engages with a clamping device 110. The clamping device is shown in detail in FIG. 2. The clamping device 110 is approximately symmetrical about vertical and horizontal axes. A primary surface 112 rests against the back surface of the electronics device. Flexible members, also known as clips 114 are engaged with the upper and lower regions of the primary surface and comprise grooves 120 that accept the raised edge 134 of the electronics device. Offset edges 116 and slots 118 (FIG. 2) located on lateral sides of the primary surface 112 provide a buckle for a strap. Smaller holes 122 arranged in a rectangular configuration about the center of the primary surface 112 provide a means for employing plastic ties or other cord-like members to fasten the device to a surface. Protrusions 126 provide a guide for said cord-like members. A central hole, 124 located at the center of the primary surface, accepts a screw for affixing the device 110 to other objects.

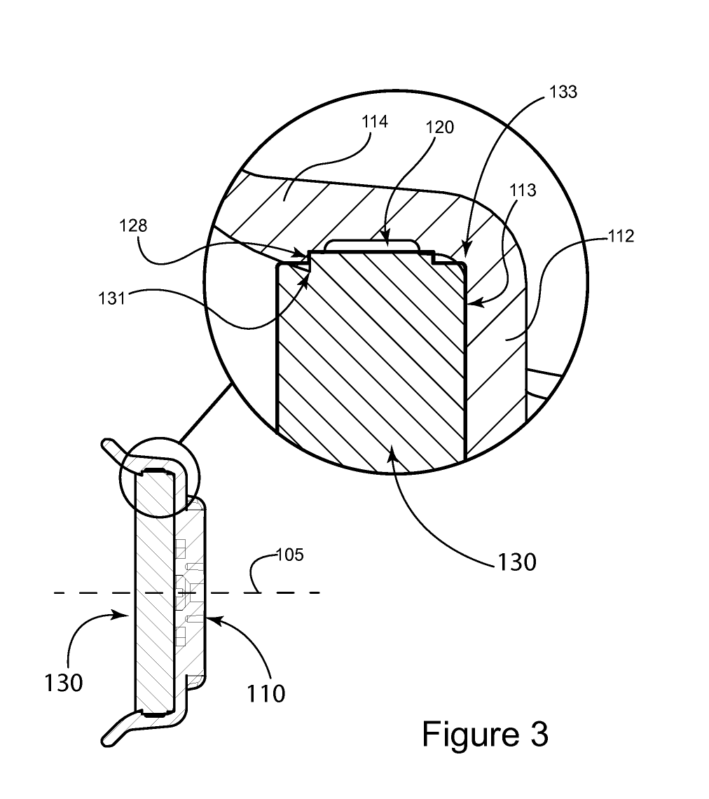

Referring to FIG. 3, a section view illustrates the engagement means between the clamping device 110 and the electronics device 130. The means of engagement is symmetrical about the horizontal centerline 105. The primary surface 112 of the clamping device engages with the back surface of the electronics device 130. The flexible tab member 114 engages with the top of the electronics device 130. The grove 120 has a notch 128 that engages with the corner of the raised edge 134 of the electronics device. A portion of material 131 interferes with the body of the electronics device, further interference, at location 133, occurs at the bend between the primary surface 112 and flexible tab 114 of the clamping device 110. Such a method of employing a small amount of material that exceeds the geometry necessary to provide a precise fit is often referred to as an interference fit. This particular interference fit provides a secure engagement between the clamping device and the electronics device sufficient to hold the electronics device securely while the user wears the device during physical activity or while the device is fastened to a vehicle or equipment such as handle bars or ski poles or the like.

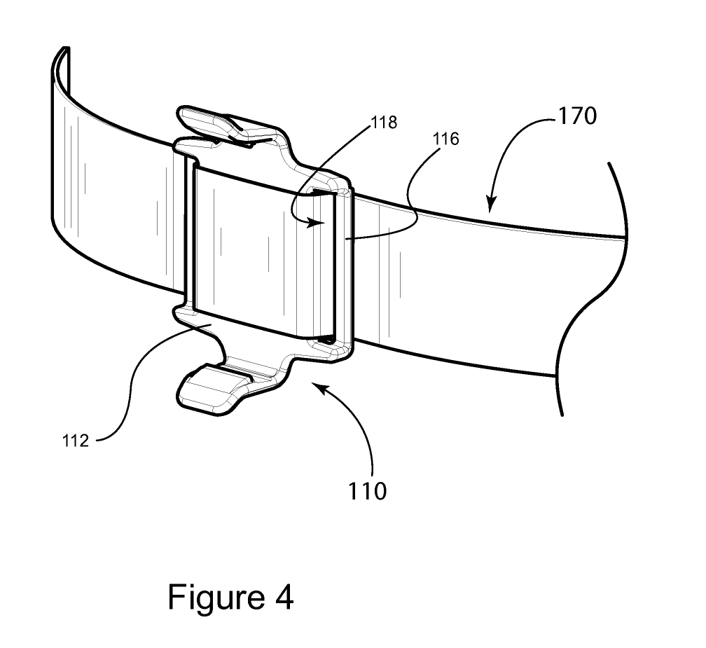

Referring to FIG. 4, the clamping device 110 is illustrated in combination with a belt or strap 170. During certain physical activities it is useful to wear a camera strapped to one's chest or around the waist as a belt. Slots 118 through both sides of the primary surface 112 of the clamping device 130 combined with edge portions 116 provide a means of engaging a belt or strap 170 as one might engage a buckle with a belt.

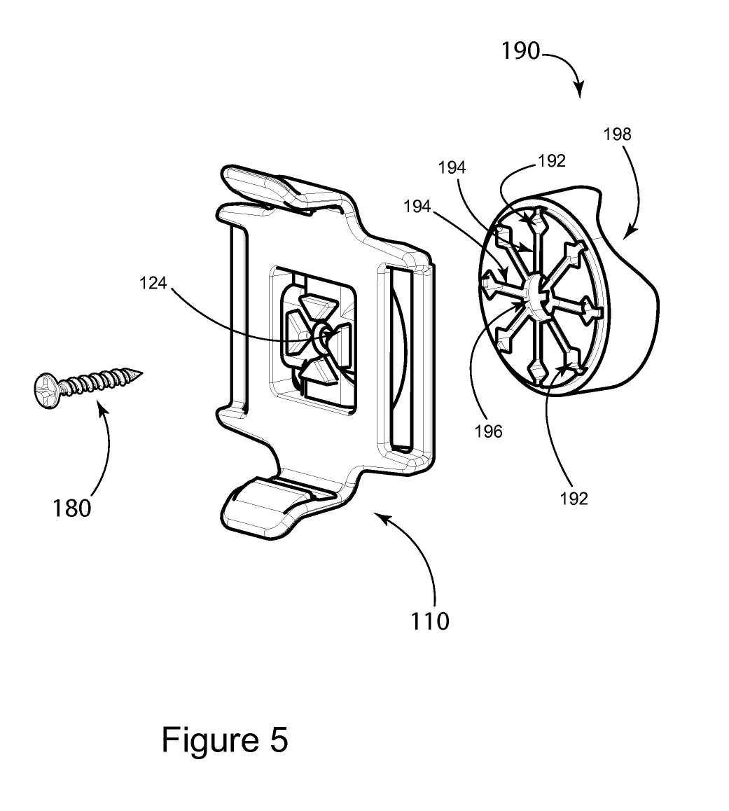

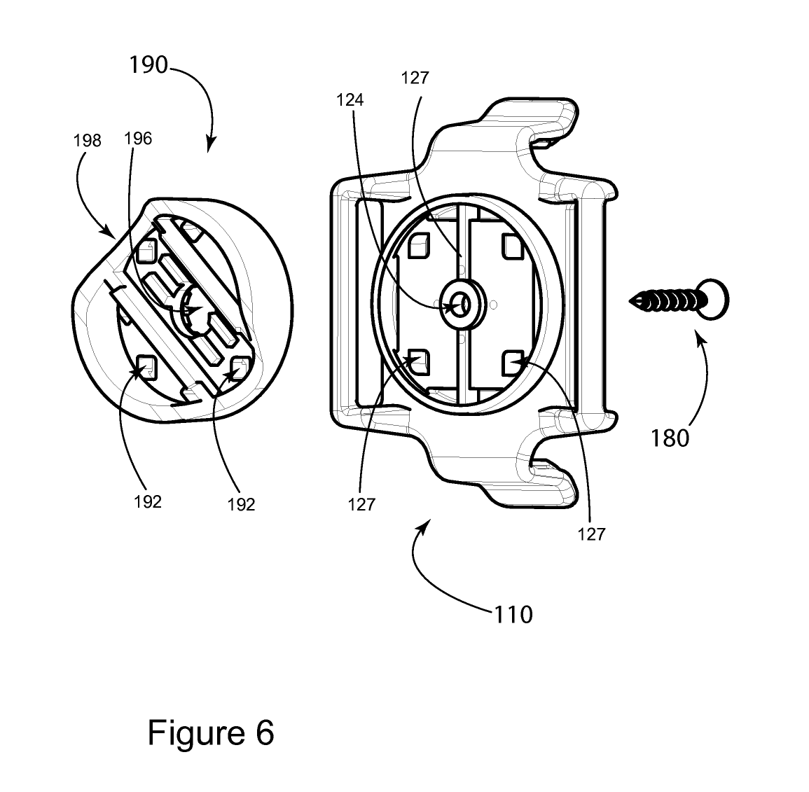

Referring to FIG. 5 and FIG. 6 a means of engaging the clamping device to a cylindrical portion of equipment or a vehicle is illustrated. The clamping device 110 engages with a spacer 190. The spacer comprises a cylindrical groove 198 for engaging with cylindrical portions of objects such as handlebars or ski poles or the like. The spacer 190 further comprises a hole in the center 196 for receiving a screw 180 that passes through the hole 124 in the clamp 110 and continues through the hole 196 to engage with the cylindrical piece of equipment (not shown).

The spacer 190 further comprises grooves 194 and holes 192. Grooves 194 are arranged radially about the spacer 190 and engage with a protrusion 127 in the clamp 110. Holes 192 are spaced radially and align with holes 127 in the clamp 110. The radial arrangement of the grooves 194 allow the spacer 190 to be rotated and affixed in a number of positions such that the clamp and its attached electronics device may be rotated to a desired orientation. Holes 127 allow for cords or plastic ties or the like to be passed through the clamp and spacer and engaged about a cylindrical portion of a piece of equipment.

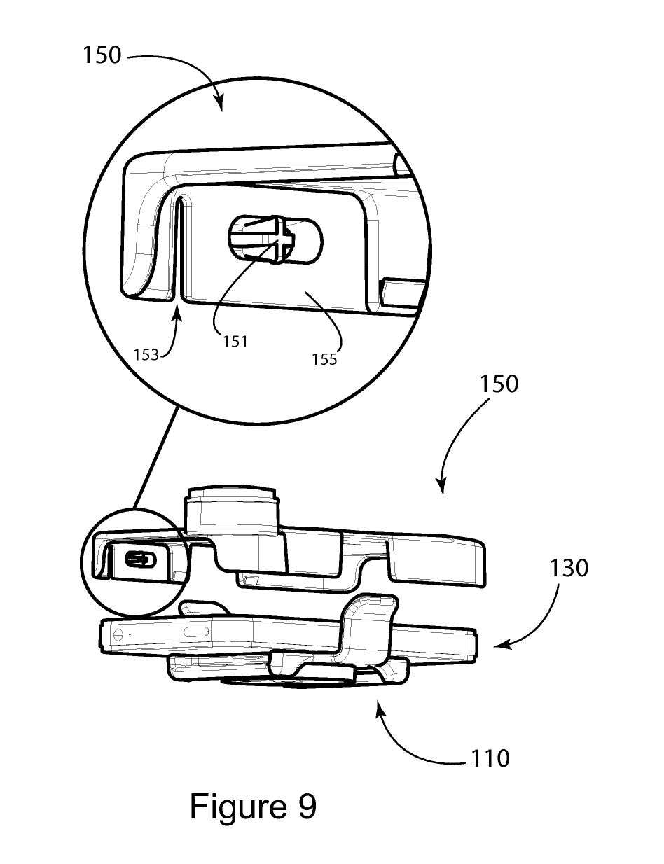

Referring to FIG. 7 through FIG. 9, an assembly of the cover 150, electronic device 130 and clamp 110 is illustrated. An integrated button cover 159 provides both protection and access to specific buttons such as button 139 where the button cover aligns with such buttons, on the electronics device 130. The integrated button cover is formed into the shape of the cover 150, has no moving parts, occupies a portion of the cover 150; and comprises a flexible portion 155, a relief slot 153 and a protrusion 151 (FIG. 9). The protrusion 151 aligns with a button such as button 139. The relief slot 153 permits a portion of the cover to flex. The flexible portion 155 of the cover 150 moves when depressed, sufficiently to depress button 139 and flexes back to its original position where it is aligned with but not depressing the button 139.

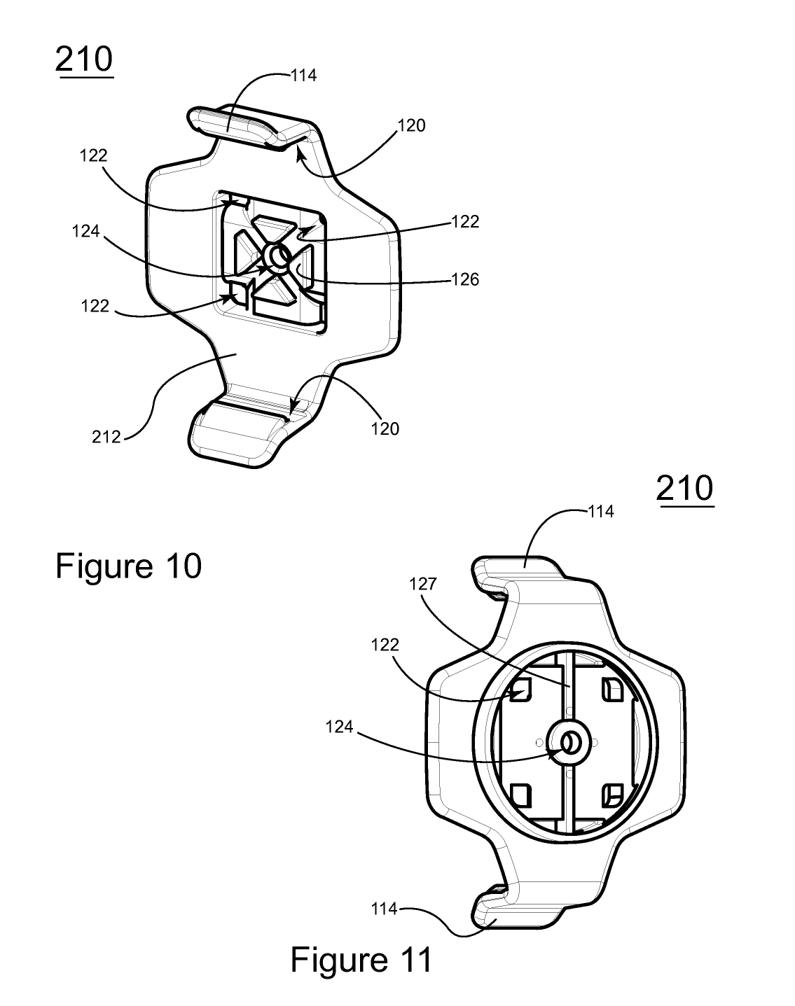

Referring to FIG. 10 and FIG. 11, an iteration of the embodiment 210 is illustrated. Like reference numerals refer to like components and features. The clamping device 210 is approximately symmetrical about vertical and horizontal axes. A primary surface 112 rests against the back surface of the electronics device. Flexible members, also known as clips 114 are engaged with the upper and lower regions of the primary surface and comprise grooves 120 that accept the raised edge 134 of the electronics device. Holes 122 arranged in a rectangular configuration about the center of the primary surface 112 provide a means for employing plastic ties or other cord-like members to fasten the device to a surface. Protrusions 126 provide a guide for said cord-like members. A central hole, 124 located at the center of the primary surface, accepts a screw for affixing the device 110 to other objects.

The present disclosure has been described with reference to exemplary embodiments. Obviously, modifications and alterations will occur to others upon reading and understanding the preceding detailed description. It is intended that the present disclosure be construed as including all such modifications and alterations insofar as they come within the scope of the appended claims or the equivalents thereof.

1. A clamping device for securing an electronics device comprising:
a primary surface;
a clamp with flexible members adapted to be engaged with the primary surface and adapted to surround said electronics device and;
at least one groove in said flexible member(s) that mates with a portion of said electronics device and;
a portion of said at least one groove that includes material that interferes with the fit of the electronics device into said groove(s) while maintaining engagement between the electronics device, the flexible members, the groove and the primary surface;
at least one slot in the clamp for engagement with a strap and;
at least one hole in the clamp for engagement with at least one cord and;
at least one hole in the clamp for engagement with a screw.

2. (canceled)

3. The clamping device of claim 1 comprising:
a rigid portion having an interior surface and an exterior surface and;
a lens engaged with the exterior surface, aligned with a camera lens of said electronics device and;
at least one recess sufficient to engage with the flexible members, and;
at least one recess to allow access to controls on said electronics device.

4. The clamping device of claim 3 further comprising:
a means to both protect and allow access to a button on the electronics device including:
at least one relief slot causing a portion of said rigid portion to flex and;
a protrusion on an interior surface of said portion that aligns with a said button, and;
a protrusion on the exterior of the cover on said portion to signify a location for depressing said button.

5. The clamping device of claim 1 further comprising a spacer that includes
a cylindrical recess for mating the spacer to cylindrical objects; and
grooves for radial indexing when engaging with a similar shaped protrusion.

6. The clamping device of claim 5 further comprising protrusions and holes for mating with the geometry of the spacer.

7. A system for engaging and holding an electronic device comprising:
a first member contoured to mate with a first surface of said electronic device;
a second member contoured to mate with a second surface of said electronic device, said second surface being opposite said first surface;
said second member having a plurality of flexible fingers adapted to wrap around sides of said electronic device and to engage corresponding slots in said first member;
whereby, said first member and said second member sandwich and hold said electronic device;
wherein said first member includes a flexible button adapted to engage a control button on said electronic device.

8. (canceled)

9. The system of claim 7 wherein said second member contains a hole adapted to receive a screw or bolt.

10. The system of claim 9 wherein said screw or bolt engages a mounting member.

11. The system of claim 7 wherein said piece of electronic equipment is a camera.

12. A method of engaging and holding a piece of electronic equipment comprising:
providing a first member contoured to mate with a first surface of said electronic device;
providing a second member contoured to mate with a second surface of said electronic device, said second surface being opposite said first surface, wherein said second member has a plurality of flexible fingers adapted to wrap around sides of said electronic device and to engage corresponding slots in said first member thereby engaging said piece of electronic equipment;
wherein said first member includes a flexible button adapted to engage a control button on said electronic device.

13. The method of claim 12 wherein said piece of electronic equipment is a camera.

14. (canceled)

15. The method of claim 12 wherein said second member contains a hole adapted to receive a screw or bolt.

16. The method of claim 15 wherein said screw or bolt engages a mounting member.
